(19) United States
(12) Patent Application Publication
(10) Pub. No.: US 2010/0147353 A1
(43) Pub. Date: Jun. 17, 2010

(54) Integrated Shunt Protection Diodes For Thin-Film Photovoltaic Cells And Modules

(76) Inventor: Kishore KAMATH, Fort Collins, CO (US)

Correspondence Address: COOLEY GODWARD KRONISH LLP;ATTN: Patent Group, Suite 1100, 777 - 6th Street, NW, WASHINGTON, DC, 20001, US

(21) Appl. No.: 12/334,860

(22) Filed: Dec. 15, 2008

(51) Int. Cl. H01L 31/042; H01L 21/20

(52) U.S. Cl. 136/244; 438/59; 257/E21.09

(57) ABSTRACT

A method for fabricating a photovoltaic cell with an integrated shunt protection diode. The photovoltaic cell and corresponding integrated shunt protection diode are created by first scribing a transparent conductive oxide layer on a substrate to define a plurality of transparent conductive oxide areas. Next, a semiconductor layer is deposited onto a surface of the transparent conductive oxide layer. This semiconductor layer is scribed to expose a portion of each of the transparent conductive oxide areas. A conductive layer is then deposited onto a surface of the semiconductor layer. Subsequently, the conductive layer is scribed into conductive areas.

### CROSS REFERENCE TO RELATED APPLICATIONS

Not applicable.

### STATEMENT REGARDING FEDERALLY-SPONSORED RESEARCH AND DEVELOPMENT

Not applicable.

### NAMES OF THE PARTIES TO A JOINT RESEARCH AGREEMENT

Not Applicable.

### BACKGROUND OF THE INVENTION

1. Field of the Invention

The present invention relates to a method for manufacturing thin-film photovoltaic modules. More particularly, the present invention relates to a method for manufacturing a thin-film photovoltaic module which includes photovoltaic cells and integrated shunt protection diodes that are manufactured from an adaptation of the standard scribing processes.

2. Related Art

Photovoltaic cells convert solar energy into electricity through the photovoltaic effect. The electricity output from each cell is in the form of a relatively low voltage. As such, photovoltaic cells can be connected in series to form a photovoltaic module, to generate a voltage desirable for general use.

When photovoltaic cells are connected in series, the current is limited by the lowest generating cell. In the worst case, if one or more cells generates no power or photocurrent due to shadow or other circumstance, the total voltage generated among the remaining cells appears across the cells that generate no power. This is because the non-generating cells create an open connection and block the current. This build up of voltage can lead to catastrophic failure of the cells and can possibly render the photovoltaic module useless.

To avoid the problems associated with the non-generating cells, a shunt diode is connected across the photovoltaic cells which will protect the non-generating cells from excessive reverse bias. Shunt protection diodes limit the maximum reverse voltage on cells not generating power to the forward voltage drop on the shunt protection diodes. This prevents permanent damage to the cells not generating power.

Module level protection can be implemented at the power block of each module, however cell level protection needs to be implemented within the module. Building the integrated cell level shunt protection within the standard manufacturing process flow is the most desirable solution.

### BRIEF SUMMARY OF THE INVENTION

Described is a method for fabricating a photovoltaic cell with an integrated shunt protection diode. The photovoltaic cell and corresponding integrated shunt protection diode are created by first scribing a transparent conductive oxide layer on a substrate to define a plurality of transparent conductive oxide areas. Next, a semiconductor layer is deposited onto a surface of the transparent conductive oxide layer. This semiconductor layer is scribed to expose a portion of each of the transparent conductive oxide areas. A conductive layer is then deposited onto a surface of the semiconductor layer. Subsequently, the conductive layer is scribed into conductive areas.

### BRIEF DESCRIPTION OF THE DRAWINGS/FIGURES

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIG. 1 is a schematic perspective view of a typical thin-film photovoltaic module that can be fabricated according to the method disclosed herein.

FIGS. 2(a)-2(g) are schematic perspective views depicting the steps in a method for fabricating a type of thin-film photovoltaic module according to the method of this invention.

FIGS. 3(a)-3(c) illustrate exemplary processes for scribing a substrate, according to embodiments of the present invention.

### DETAILED DESCRIPTION

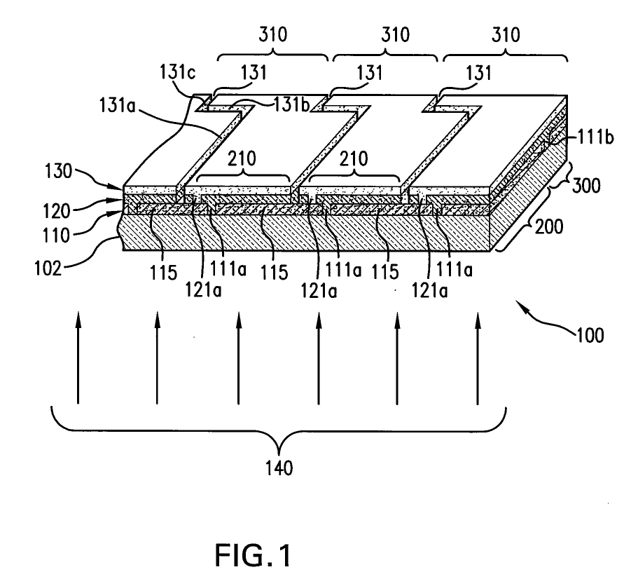

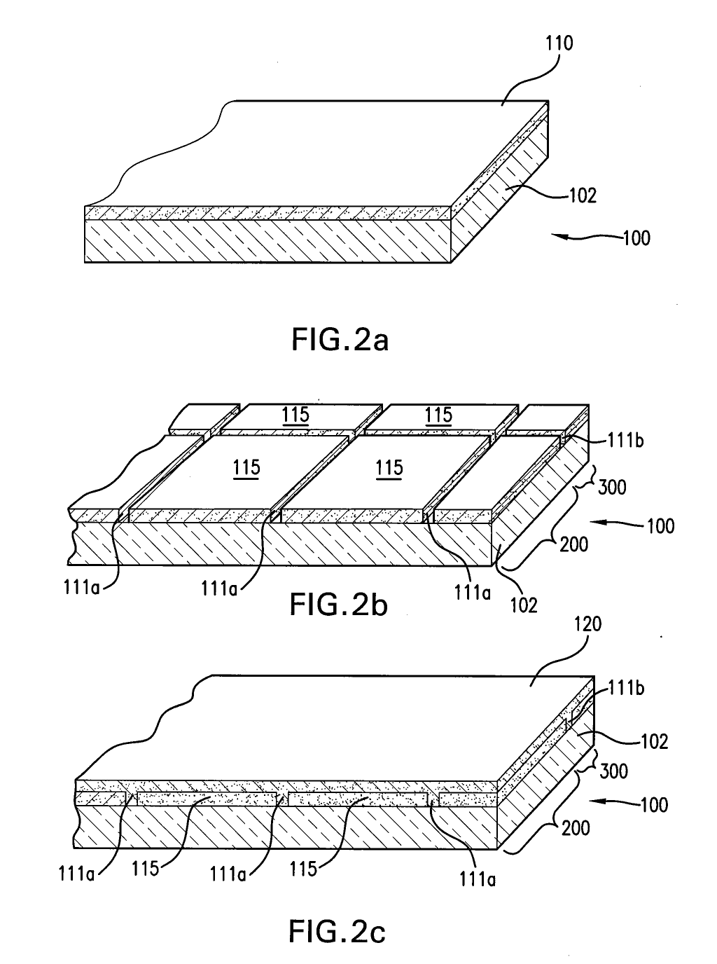

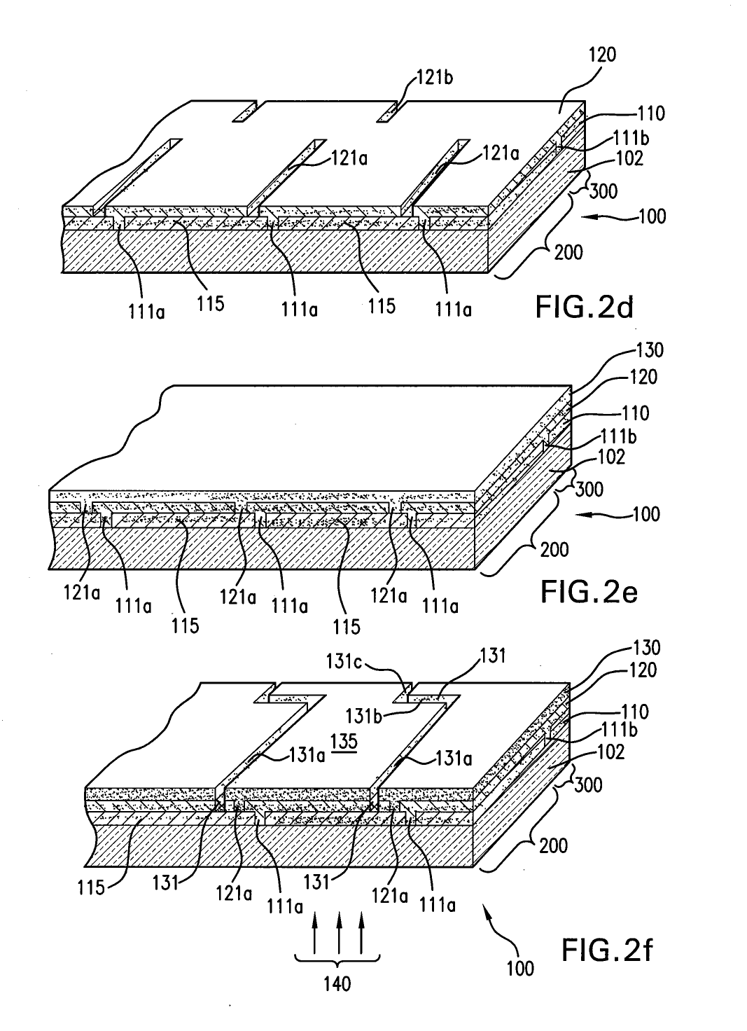

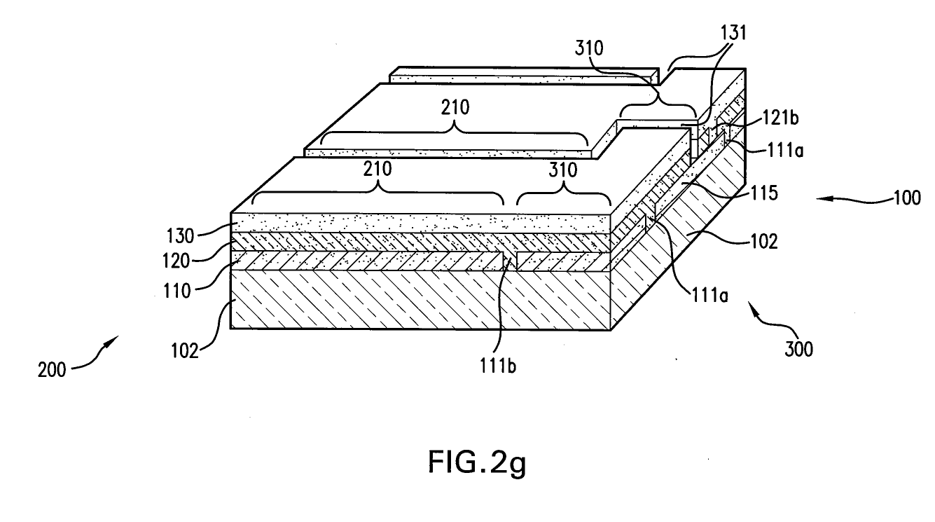

FIG. 1 shows a thin-film photovoltaic module 100 comprised of a plurality of series connected photovoltaic cells 210 and a plurality of integrated shunt protection diodes 310 connected in parallel with photovoltaic cells 210 subjected to solar radiation or other light 140. Photovoltaic cells 210 and integrated shunt protection diodes 310 are formed on a transparent substrate 102. Each photovoltaic cell 210 and integrated shunt protection diode 310 are made of a transparent conductive oxide (TCO) layer 110, a semiconductor layer 120, and a conductive layer 130. TCO areas 115 are separated by first grooves 111a and 111b. For better illustration, FIG. 2(b) shows TCO areas 115 and first grooves 111a and 111b.

First grooves 111b separate photovoltaic module 100 into a photovoltaic region 200 and an integrated shunt protection diode region 300. First grooves 111a and 111b are filled with semiconductor layer 120. Semiconductor layer 120 in grooves 111a and 111b electrically insulates and isolates TCO areas 115. Semiconductor layer 120 contains second grooves 121a and 121b which are filled with conductive layer 130. FIG. 2(d) provides a better illustration of second grooves 121a and 121b.

Conductive layer 130 in grooves 121a and 121b provides an electrical connection between TCO layer 110 and conductive layer 130. The electrical connection between TCO layer 110 and conductive layer 130 through second grooves 121a connect photovoltaic cells 210 in series. The electrical connection between TCO layer 110 and conductive layer 130 through second grooves 121b connects integrated shunt protection diodes 310 in parallel with photovoltaic cells 210. Conductive layer 130 contains third grooves 131. Third grooves 131 comprise three segments: 131a, 131b, and 131c. Third grooves 131 form separation in conductive layer 130 and semiconductor layer 120 to form photovoltaic cells 210 and integrated shunt protection diodes 310. For better illustration, FIG. 2(f) and FIG. 2(g) show third grooves 131 and segments 131a, 131b, and 131c.

FIG. 2(g) is an alternate view of photovoltaic module 100. This figure better shows photovoltaic cell 210 and integrated shunt protection diode 310 electrically separated by first groove 111b.

The method for forming photovoltaic module 100 will now be described with reference to FIGS. 2(a) through 2(g). It should be understood that while the description below is directed to a semiconductor layer utilizing cadmium sulfide and cadmium telluride (CdS/CdTe), this invention is not so limited and can be used to make other photovoltaic devices such as thin-film photovoltaic devices containing amorphous silicon, copper-indium selenide (CIS), organic dyes, or other materials as the semiconductor layer.

TCO layer 110, such as zinc oxide, on substrate 102 is first scribed into TCO areas 115. First grooves 111a and 111b are formed with first grooves 111b separating photovoltaic module 100 into a photovoltaic region 200 and an integrated shunt protection diode region 300.

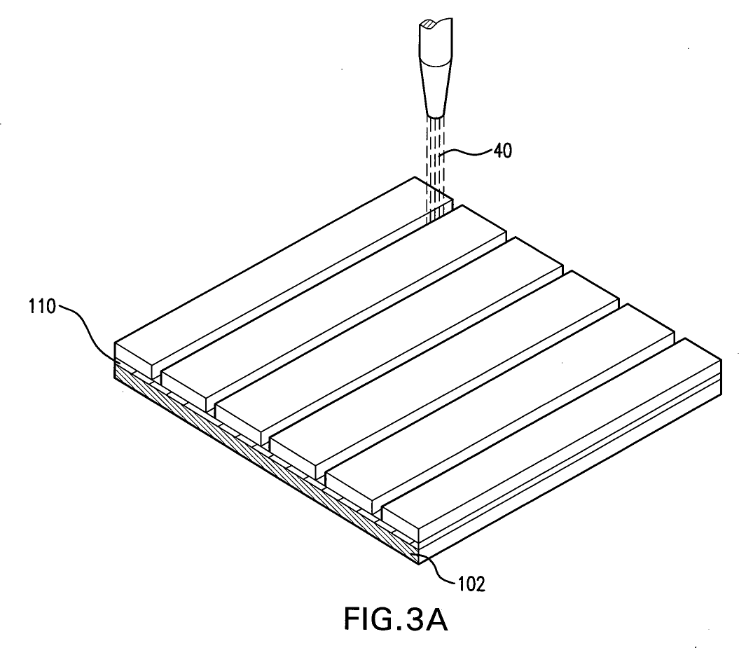

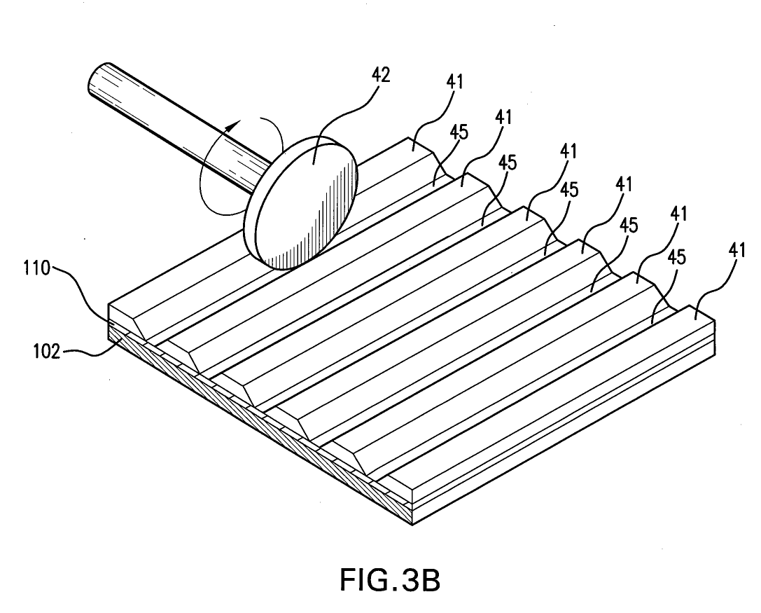

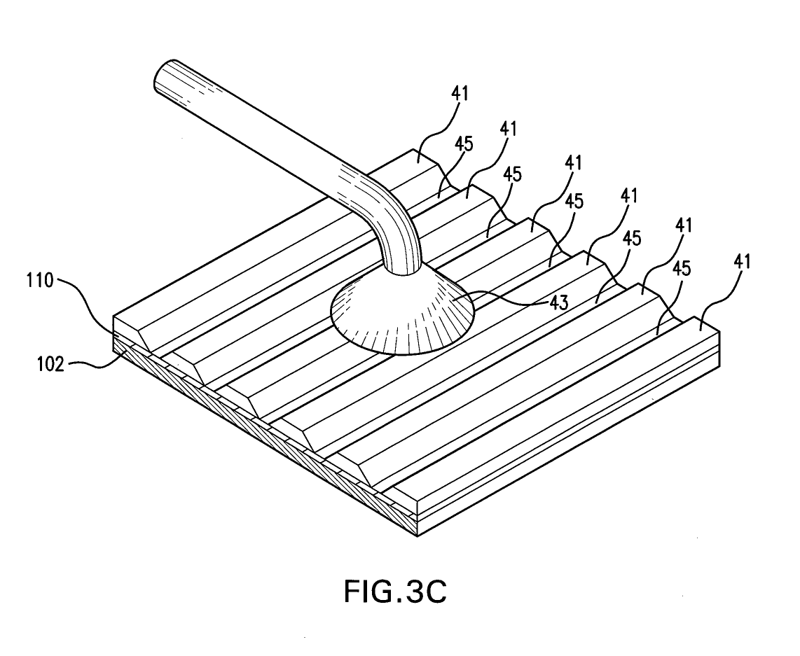

FIGS. 3A-3C illustrate exemplary scribing processes. The laser scribing shown in FIG. 3A is accomplished by directing one or more laser beams 40 at substrate 102. Laser beam 40 is scanned across TCO layer 110 in the desired pattern thereby removing portions of TCO layer 110.

In FIG. 3B, rotating wire brush 42 is brought into contact with substrate 102 through openings 45 in a mask 41 to remove portions of TCO layer 110 from substrate 102. Openings 45 in mask 41 can be tapered in cross section and are narrower near the contact of mask 41 and film layers 40, thereby facilitating entry of rotating brush 42 into openings 45. In one example, mask 41 can be coated with a hard coating, including, but not limited to, titanium nitride, to reduce wear.

The exemplary scribing process of FIG. 3B does not necessarily require a precisely-defined rotating brush 42, as openings 45 in the mask 41 define an area of TCO layer 110 that will be removed. In such a case, rotating wire brush 42 is passed axially along openings 45 in mask 41 over substrate 102 to perform a scribe. In an additional embodiment, a plurality of rotating metal brushes 42 may scribe substrate 102 in a single process.

In FIG. 3C, an abrasive blast 43 passes through openings 45 in mask 41 to remove portions of TCO layer 110 from substrate 102. Similar to the embodiment of FIG. 3B, a precisely-defined abrasive blast 43 is not required, as mask 41 defines an area of film that will be removed. Abrasive blast 43 passes over substrate 102 to perform a scribe, and a respective abrasive blast may enter more than one opening 45 in mask 41. As such, a single abrasive blast 43 may perform more than one scribe for each pass over substrate 102. In an additional embodiment, a plurality of abrasive blasts 43 may complete a corresponding plurality of scribes of a single substrate in a single pass along the axis of openings 45 in mask 41.

The exemplary scribing processes of FIGS. 3A-3C may be used to scribe through the various layers in photovoltaic cell 100. In an additional embodiment, rotating brush 42 may be used in conjunction with abrasive blast 43 to remove the proper layer of photovoltaic module 100.

A semiconductor layer 120, such as CdS/CdTe, is next deposited onto TCO layer 110. Semiconductor layer 120 deposition is preferably by physical vapor deposition techniques, especially vacuum sublimination deposition. Semiconductor layer 120 occupies grooves 111a and 111b electrically isolating TCO areas 115.

A second scribe is performed on semiconductor layer 120. This second scribe removes a portion of the semiconductor layer 120, thus exposing TCO layer 110 through second grooves 121a and 121b. Second grooves 121a and 121b do not extend past first grooves 111b.

A conductive layer 130, such as nickel, is next deposited onto semiconductor layer 120. Deposition of conductive layer 130 is preferably by sputtering. Conductive layer 130 occupies second grooves 121a and 121b which enables an electrical connection between conductive layer 130 and TCO layer 110.

A third scribe is performed on conductive layer 130 and semiconductor layer 120 which creates third grooves 131. This third scribe removes a portion of conductive layer 130 and semiconductor layer 120 isolating conductive layer 130 and semiconductor layer 120 into conductive areas 135. Third grooves 131 are scribed nonlinearly, and are comprised of three segments: 131a, 131b, 131c. First segments 131a of third grooves 131 are parallel to first segments 131a and extend past first groove 111b. Second segments 131b are parallel to first groove 111b. Third segments 131c of third grooves 131 are parallel to first grooves 111a and extend to the end of photovoltaic module 100. Third grooves 131 along with first groove 111b separate photovoltaic module 100 into photovoltaic cells 210 and integrated shunt protection diodes 310.

In photovoltaic region 200, the electrical connection between conductive layer 130 and TCO layer 110 through second groove 121a enables photovoltaic cells 210 to be connected in series. The electrical connection between conductive layer 130 and TCO layer 110 though second groove 121b enables integrated shunt protection diodes 310 to be connected in parallel with photovoltaic cells 210.

During normal operation, current flows through series connected solar cells 210. However, if one or more photovoltaic cells 210 is not generating voltage and thus blocking current, the current will flow around the one or more non-generating cells 210 through the respective adjacent integrated shunt protection diode 310. The flow through integrated shunt protection diode 310 prevents excessive build up of reverse bias on non-generating cells 210. Excessive build up of reverse bias on non-generating cells 210 could lead to catastrophic failure of non-generating cells 210 and could possibly render photovoltaic module 100 useless.

In another embodiment, substrate 102 of photovoltaic module 100 is painted or taped on integrated shunt protection diode region 300 so as to prevent the integrated shunt protection diodes 310 from seeing illumination.

The method for creating the photovoltaic module in the present invention includes the following advantages:

(1) There is minimum power loss during normal operation. Current through the integrated shunt protection diode is limited to reverse current which can be negligible.

(2) The cells are protected during “dark” condition and the cells function normally when the cells are illuminated.

(3) The integrated shunt protection diodes provide continuous protection of the photovoltaic cells with a fast response time.

(4) These integrated shunt protection diodes can be implemented within the standard scribing process used in manufacturing.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

What is claimed is:

1. A thin-film photovoltaic module comprising:
a plurality of series connected solar cells; and
a plurality of integrated shunt protection diodes connected in parallel to the plurality of solar cells to protect the solar cells against open connections;
wherein each of the solar cells are scribed to form a corresponding one of the plurality of diodes.

2. A method for fabricating a photovoltaic cell with a shunt protection diode that is integrated during the scribing process, comprising:
scribing a transparent conductive oxide (TCO) layer on a substrate to define a plurality of TCO areas;
depositing at least one semiconductor layer onto a surface of the TCO layer;
scribing a portion of the semiconductor layer, to expose a portion of each of the TCO areas;
depositing a conductive layer onto a surface of the semiconductor layer; and
scribing the conductive layer and semiconductor layer to define a plurality of conductive areas.

3. The method of claim 2 wherein the semiconductor layer is deposited through a physical vapor deposition technique.

4. The method of claim 3 wherein the semiconductor layer is deposited through a sublimination process.

5. The method of claim 2 wherein the semiconductor layer comprises CdS/CdTe.

6. The method of claim 2 wherein the TCO layer comprises tin oxide.

7. The method of claim 2 wherein the conductive layer comprises nickel.

8. The method of claim 2 wherein the conductive layer comprises molybdenum.

9. The method of claim 2 wherein the photovoltaic cell is scribed with a laser.

10. The method of claim 2 wherein the photovoltaic cell is scribed with a rotating metal brush.

11. The method of claim 2 wherein the photovoltaic cell is scribed with an abrasive blast.

12. The method of claim 2 wherein photovoltaic cell is scribed with chemicals.

13. The method of claim 2 wherein the integrated shunt protection diode is prevented from seeing illumination.

14. A method for fabricating a thin-film photovoltaic cell with a shunt protection diode that is integrated during the scribing process, comprising:
scribing a TCO layer on a substrate to define a plurality of TCO areas;
depositing at least one semiconductor layer onto a surface of the TCO layer;
scribing a portion of the semiconductor layer, to expose a portion of each of the TCO areas;
depositing a conductive layer onto a surface of the semiconductor layer; and
scribing the conductive layer and semiconductor layer to define a plurality of conductive areas.

15. A method for fabricating a photovoltaic cell with a diode that is integrated during the manufacturing process, comprising:
removing a portion of a TCO layer on a substrate to define a plurality of TCO areas;
depositing at least one semiconductor layer onto a surface of the TCO layer;
removing a portion of the semiconductor layer, to expose a portion of each of the TCO areas;
depositing a conductive layer onto a surface of the semiconductor layer; and
removing a portion of the conductive layer and semiconductor layer to define a plurality of conductive areas.
